(19) United States
(12) Patent Application Publication
(10) Pub. No.: US 2024/0305195 A1
(43) Pub. Date: Sep. 12, 2024

(54) DIRECT CURRENT TO DIRECT CURRENT CONVERTER AND DISPLAY DEVICE INCLUDING THE SAME

(71) Applicant: Samsung Display Co., LTD., Yongin-si (KR)

(72) Inventors: JEONGMIN SEO, Yongin-si (KR); SUNGCHUN PARK, Yongin-si (KR)

(21) Appl. No.: 18/388,834

(22) Filed: Nov. 11, 2023

(30) Foreign Application Priority Data
Mar. 8, 2023 (KR) 10-2023-0030496

(51) Int. Cl. H02M 3/158; G09G 3/20; H02M 1/00; H02M 1/32

(52) U.S. Cl. CPC H02M 3/158; G09G 3/20; H02M 1/0032; H02M 1/32; G09G 2330/021; G09G 2330/028

(57) ABSTRACT

A direct current to direct current converter includes a switcher which generates an output voltage based on an external input voltage, and a controller which controls the switcher based on a pulse width modulation signal. The controller counts the number of switching of the pulse width modulation signal in a pulse skip mode of a low-power mode, generate a count value, and determines a short circuit defect when the count value is equal to or greater than a reference count value.

This application claims priority to Korean Patent Application No. 10-2023-0030496, filed on Mar. 8, 2023, and all the benefits accruing therefrom under 35 U.S.C. § 119, the content of which in its entirety is herein incorporated by reference.

### BACKGROUND

### 1. Field

Embodiments of the inventive concept relate to a direct current to direct current (“DC-DC”) converter and a display device including the same. More particularly, embodiments of the inventive concept relate to a DC-DC converter and a display device including the same for determining a short circuit defect.

### 2. Description of the Related Art

Generally, a display device may include a display panel and a direct current to direct current (“DC-DC”) converter. The DC-DC converter may convert an external input voltage into a first power voltage and a second power voltage lower than the first power voltage. The display panel may be driven using the first power voltage and the second power voltage.

The display device may be driven in a normal mode or a low-power mode. The low-power mode may mean a mode in which the display panel displays a time image, a date image, or the like even in a standby (or sleep) state of the display device. In an embodiment, the low-power mode may be an AOD mode. In the low-power mode, the DC-DC converter may output the second power voltage ELVSS by changing a driving method, and may reduce power consumption due to switching.

The DC-DC converter may include a current sensor to measure the driving current of the display panel. When the display panel includes a short circuit defect (e.g., a fine short circuit defect), a driving current of the display panel may increase, and an output voltage of the DC-DC converter may decrease. When the output voltage decreases to be equal to or less than a predetermined voltage, the DC-DC converter determine a short circuit defect of the display panel.

the current sensor may not operate in the low-power mode unlike the normal mode. Therefore, the DC-DC converter may not determine the short circuit defect of the display panel in the low-power mode.

### SUMMARY

Embodiments of the inventive concept provide a direct current to direct current (“DC-DC”) converter for determining a short circuit defect in a low-power mode.

Embodiments of the inventive concept provide a display device including the DC-DC converter.

In an embodiment of a DC-DC converter according to the inventive concept, the DC-DC converter includes a switcher which generates an output voltage based on an external input voltage and a controller which controls the switcher based on a pulse width modulation signal. The controller counts a number of switching of the pulse width modulation signal in a pulse skip mode of a low-power mode to generate a count value, and determines a short circuit defect when the count value is equal to or greater than a reference count value.

In an embodiment, the controller may convert the pulse skip mode of the low-power mode into a pulse width modulation mode when the count value is equal to or greater than the reference count value.

In an embodiment, the switcher may include a voltage divider which divides the output voltage to generate a feedback voltage, an error amplifier which amplifies a voltage difference between the feedback voltage and a feedback reference voltage and outputs a control voltage, and a comparator which compares the control voltage with a skip reference voltage and to output a skip control signal.

In an embodiment, the controller may skip active pulses of the pulse width modulation signal when the skip control signal is at a relatively high level, and may not skip the active pulses of the pulse width modulation signal when the skip control signal is at a relatively low level.

In an embodiment, the controller may reset the count value when the skip control signal is at a relatively high level, and to count the number of switching of the pulse width modulation signal to generate the count value when the skip control signal is at a relatively low level.

In an embodiment, the controller may include a first flip-flop to a fourth flip-flop, in which the first flip-flop outputs a first inverted output signal, which is an inverted output signal of the first flip-flop, using a pulse width modulation clock signal, and simultaneously feeds back the first inverted output signal to a first input signal, which is an input signal of the first flip-flop, the second flip-flop outputs a second inverted output signal, which is an inverted output signal of the second flip-flop, using the first inverted output signal, and simultaneously feeds back the second inverted output signal to a second input signal, which is an input signal of the second flip-flop, the third flip-flop outputs a third inverted output signal, which is an inverted output signal of the third flip-flop, using the second inverted output signal, and simultaneously feeds back the third inverted output signal to a third input signal, which is an input signal of the third flip-flop, and the fourth flip-flop outputs a fourth inverted output signal, which is an inverted output signal of the fourth flip-flop, using the third inverted output signal, and simultaneously feeds back the fourth inverted output signal to a fourth input signal, which is an input signal of the fourth flip-flop.

In an embodiment of a DC-DC converter according to the inventive concept, the DC-DC converter includes a switcher which generates an output voltage based on an external input voltage and a controller which controls the switcher. The controller compares a slope voltage with a control voltage and a pulse width modulation reference voltage in a pulse width modulation mode of a low-power mode to control a width of an active pulse of a pulse width modulation signal, and the switcher may determine a short circuit defect when the output voltage is lower than a short circuit defect reference voltage.

In an embodiment, the slope voltage may gradually increase when a pulse width modulation clock signal has a falling edge.

In an embodiment, the pulse width modulation signal may have an active level when the slope voltage gradually increases.

In an embodiment, the slope voltage may have an inactive level when the slope voltage gradually increases to be equal to the control voltage or the pulse width modulation reference voltage.

In an embodiment, the pulse width modulation signal may have an inactive level when the slope voltage has the inactive level.

In an embodiment, the switcher may include a voltage divider which divides the output voltage to generate a feedback voltage, an error amplifier which amplifies a voltage difference between the feedback voltage and a feedback reference voltage and outputs a control voltage, and a comparator which compares the slope voltage with the control voltage and the pulse width modulation reference voltage and outputs a maximum on-time signal.

In an embodiment, the switcher may further include a multiplexer which selects and outputs one of the pulse width modulation reference voltages.

In an embodiment, wherein the switcher may further include a short circuit defect comparator which compares the output voltage with the short circuit defect reference voltage.

In an embodiment of a display device according to the inventive concept, the display device includes a display panel and a DC-DC converter which applies an output voltage to the display panel. The DC-DC converter includes a switcher which generates the output voltage based on an external input voltage, and a controller which controls the switcher based on a pulse width modulation signal, and the controller counts a number of switching of the pulse width modulation signal in a pulse skip mode of a low-power mode to generate a count value, and determines a short circuit defect when the count value is equal to or greater than a reference count value.

In an embodiment, the controller may convert the pulse skip mode of the low-power mode into a pulse width modulation mode when the count value is equal to or greater than the reference count value.

In an embodiment, the switcher may include a voltage divider which divides the output voltage to generate a feedback voltage, an error amplifier which amplifies a voltage difference between the feedback voltage and a feedback reference voltage and outputs a control voltage, and a comparator which compares the control voltage with a skip reference voltage and outputs a skip control signal.

In an embodiment, the controller may skip active pulses of the pulse width modulation signal when the skip control signal is at a relatively high level, and may not skip the active pulses of the pulse width modulation signal when the skip control signal is at a relatively low level.

In an embodiment, the controller may reset the count value when the skip control signal is at a relatively high level, and to count the number of switching of the pulse width modulation signal to generate the count value when the skip control signal is at a relatively low level.

In an embodiment, the controller may include a first flip-flop to a fourth flip-flop, in which the first flip-flop outputs a first inverted output signal, which is an inverted output signal of the first flip-flop, using a pulse width modulation clock signal, and simultaneously feeds back the first inverted output signal to a first input signal, which is an input signal of the first flip-flop, the second flip-flop outputs a second inverted output signal, which is an inverted output signal of the second flip-flop, using the first inverted output signal, and simultaneously feeds back the second inverted output signal to a second input signal, which is an input signal of the second flip-flop, the third flip-flop outputs a third inverted output signal, which is an inverted output signal of the third flip-flop, using the second inverted output signal, and simultaneously feeds back the third inverted output signal to a third input signal, which is an input signal of the third flip-flop, and the fourth flip-flop outputs a fourth inverted output signal, which is an inverted output signal of the fourth flip-flop, using the third inverted output signal, and simultaneously feeds back the fourth inverted output signal to a fourth input signal, which is an input signal of the fourth flip-flop.

According to the DC-DC converter and the display device including the DC-DC converter in the embodiments, the DC-DC converter may include the switcher to generate the output voltage based on the external input voltage, and the controller to control the switcher. The controller may generate the count value by counting the number of switching of the pulse width modulation signal in the pulse skip mode of the low-power mode. Accordingly, when the count value is equal to or greater than the reference count value, the short circuit defect may be determined.

According to the DC-DC converter and the display device including the DC-DC converter in the embodiments, the DC-DC converter may include the switcher to generate the output voltage based on the external input voltage, and the controller to control the switcher. The controller may compare the slope voltage with the control voltage and the pulse width modulation reference voltage in the pulse skip mode of the low-power mode to control a width of the active pulse of the pulse width modulation signal. The switcher may determine the short circuit defect when the output voltage is lower than the short circuit defect reference voltage.

### BRIEF DESCRIPTION OF THE DRAWINGS

The above and other features of embodiments of the inventive concept will become more apparent by describing in detailed embodiments thereof with reference to the accompanying drawings, in which:

FIG. 1 is a block diagram for illustrating an embodiment of a display device according to the inventive concept;

FIG. 2 is a block diagram for illustrating a direct current to direct current (“DC-DC”) converter of FIG. 1;

FIG. 3 is a conceptual diagram for illustrating a low-power mode;

FIG. 4 is a block diagram for illustrating an embodiment of a second converter of FIG. 2;

FIG. 5 is a block diagram for illustrating a controller of FIG. 3;

FIG. 6 is a timing diagram for illustrating an operation of the controller 700 of FIG. 3 when the DC-DC converter is shut down due to the short circuit defect of the display panel 100 in the low-power mode;

FIG. 7 is a block diagram for illustrating an embodiment of the second converter 620a of FIG. 2;

FIG. 8 is a timing diagram for illustrating an operation of the second converter 620b of FIG. 7;

FIG. 9 is a conceptual diagram for illustrating the short circuit defect comparator of FIG. 7;

FIG. 10 is a block diagram for illustrating an electronic device; and

FIG. 11 is a diagram for illustrating an embodiment in which the electronic device of FIG. 10 is implemented as a smart phone.

### DETAILED DESCRIPTION

Hereinafter, embodiments of the inventive concept will be described in detail with reference to the accompanying drawings.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

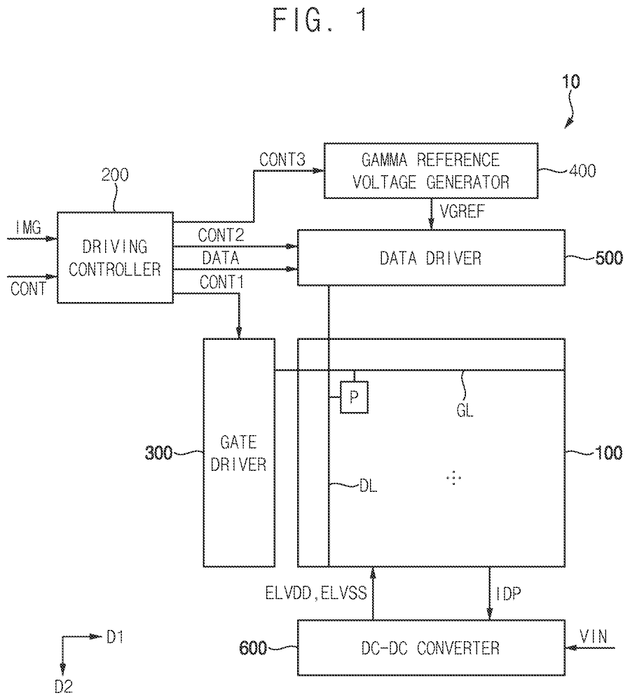

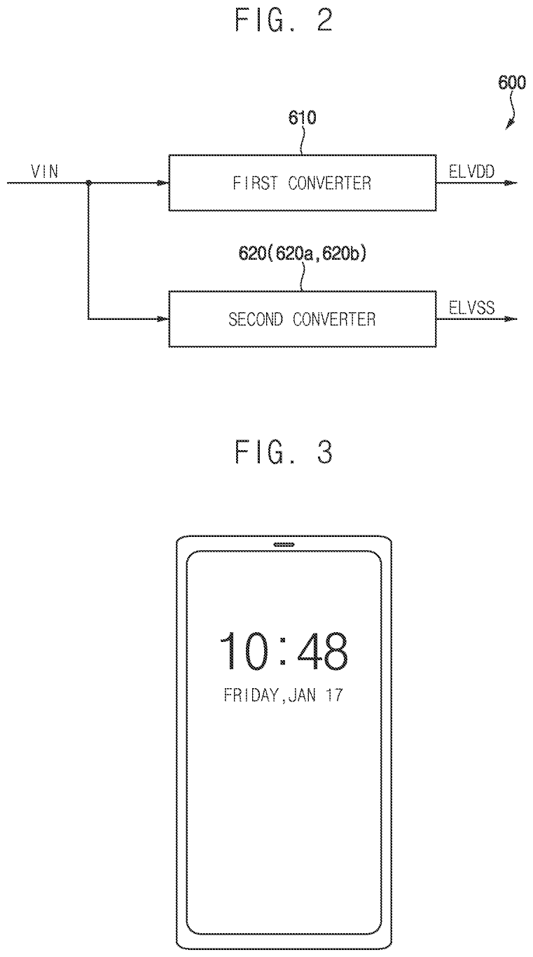

FIG. 1 is a block diagram for illustrating an embodiment of a display device 10 according to the inventive concept. FIG. 2 is a block diagram for illustrating a direct current to direct current (“DC-DC”) converter 600 of FIG. 1. FIG. 3 is a conceptual diagram for illustrating a low-power mode.

Referring to FIGS. 1 to 3, the display device 10 may include a display panel 100 and a display panel driver. The display panel driver may include a driving controller 200, a gate driver 300, a gamma reference voltage generator 400, a data driver 500, and a DC-DC converter 600.

In an embodiment, the driving controller 200 and the data driver 500 may be unitary, for example. In an embodiment, the driving controller 200, the gamma reference voltage generator 400, and the data driver 500 may be unitary. In an embodiment, the driving controller 200, the gate driver 300, the gamma reference voltage generator 400, and the data driver 500 may be unitary. A driving module in which at least the driving controller 200 and the data driver 500 are unitary may be also referred to as a timing controller embedded data driver (“TED”).

The display panel 100 may include a display region to display an image and a peripheral region disposed adjacent to the display region.

In an embodiment, the display panel 100 may be an organic light-emitting diode display panel including an organic light-emitting diode, for example. In another embodiment, the display panel 100 may be a quantum-dot organic light-emitting diode display panel including an organic light-emitting diode and a quantum-dot color filter. In another embodiment, the display panel 100 may be a quantum-dot nano light-emitting diode display panel including a nano light-emitting diode and a quantum-dot color filter. In another embodiment, the display panel 100 may be a liquid crystal display panel including a liquid crystal layer.

The display panel 100 may include gate lines GL, data lines DL, and pixels P electrically connected to the gate lines GL and the data lines DL. The gate lines GL may extend in a first direction D1, and the data lines DL may extend in a second direction D2 crossing the first direction D1.

The driving controller 200 may receive input image data IMG and an input control signal CONT from an external device (not shown). In an embodiment, the input image data IMG may include red image data, green image data, and blue image data, for example. By embodiments, the input image data IMG may further include white image data. In another embodiment, the input image data IMG may include magenta image data, yellow image data, and cyan image data. The input control signal CONT may include a master clock signal and a data enable signal. The input control signal CONT may further include a vertical synchronization signal and a horizontal synchronization signal.

The driving controller 200 may generate a first control signal CONT1, a second control signal CONT2, a third control signal CONT3, and a data signal DATA based on the input image data IMG and the input control signal CONT.

The driving controller 200 may generate the first control signal CONT1 for controlling an operation of the gate driver 300 based on the input control signal CONT and output the same to the gate driver 300. The first control signal CONT1 may include a vertical start signal and a gate clock signal.

The driving controller 200 may generate the second control signal CONT2 for controlling an operation of the data driver 500 based on the input control signal CONT and output the same to the data driver 500. The second control signal CONT2 may include a horizontal start signal and a load signal.

The driving controller 200 may generate the data signal DATA based on the input image data IMG. The driving controller 200 may output the data signal DATA to the data driver 500.

The driving controller 200 may generate the third control signal CONT3 for controlling an operation of the gamma reference voltage generator 400 based on the input control signal CONT and output the same to the gamma reference voltage generator 400.

The gate driver 300 may generate gate signals for driving the gate lines GL in response to the first control signal CONT1 received from the driving controller 200. The gate driver 300 may output the gate signals to the gate lines GL.

In an embodiment, the gate driver 300 may be integrated on the peripheral region of the display panel 100. In an embodiment, the gate driver 300 may be disposed (e.g., mounted) on the peripheral region of the display panel 100.

The gamma reference voltage generator 400 may generate a gamma reference voltage VGREF in response to the third control signal CONT3 received from the driving controller 200. The gamma reference voltage generator 400 may provide the gamma reference voltage VGREF to the data driver 500. The gamma reference voltage VGREF may have a value corresponding to each data signal DATA.

In an embodiment, the gamma reference voltage generator 400 may be disposed in the driving controller 200 or disposed in the data driver 500.

The data driver 500 may receive the second control signal CONT2 and the data signal DATA from the driving controller 200, and may receive the gamma reference voltage VGREF from the gamma reference voltage generator 400. The data driver 500 may convert the data signal DATA into an analog data voltage by the gamma reference voltage VGREF. The data driver 500 may output the data voltage to the data line DL.

The DC-DC converter 600 may generate a first power voltage ELVDD and a second power voltage ELVSS by an external input voltage VIN, and may provide the first power voltage ELVDD and the second power voltage ELVSS to the display panel 100. In an embodiment, the first power voltage ELVDD may be a relatively high power voltage, and the second power voltage ELVSS may be a relatively low power voltage, for example. The DC-DC converter 600 may include a first converter 610 and a second converter 620. The first power voltage ELVDD may be generated by the first converter 610. The second power voltage ELVSS may be generated by the second converter 620. In an embodiment, the first converter 610 may be a boost converter, for example. In an embodiment, the second converter 620 may be an inverting buck-boost converter, for example. In an embodiment, the second converter 620 may include first and second converters 620a and 620b which will be described later.

The DC-DC converter 600 may receive a driving current IDP of the display panel 100. The driving current IDP of the display panel 100 may be generated based on the first power voltage ELVDD and the second power voltage ELVSS. The DC-DC converter 600 may include a current sensor (not shown) to measure the driving current IDP of the display panel 100.

When the display panel 100 includes a short circuit defect (e.g., a fine short circuit defect), the driving current IDP of the display panel 100 may increase, and an output voltage of the DC-DC converter 600 may decrease. When the output voltage decreases to be equal to or less than the short circuit defect reference voltage, it may be determined that the display panel 100 includes the short circuit defect. In order to determine the short circuit defect of the display panel 100, the DC-DC converter 600 may include a short circuit defect comparator to compare the output voltage with the short circuit defect reference voltage.

The DC-DC converter 600 may be driven in a normal mode or a low-power mode. As shown in FIG. 3, the low-power mode may mean a mode in which the display panel displays a time image, a date image, or the like even in a standby (or sleep) state of the display device 10. In an embodiment, the low-power mode may be an always-on display (“AOD”) mode, for example. In the low-power mode, the DC-DC converter 600 may output the second power voltage ELVSS by changing a driving method, and may reduce power consumption due to switching. In an embodiment, the DC-DC converter 600 may be driven using a minimum amount of components in the low-power mode, for example. In an embodiment, the driving current IDP of the display panel 100 may be lower in the low-power mode than in the normal mode, and accordingly, a luminance of images may be lower, for example.

The current sensor may not operate in the low-power mode unlike the normal mode. Thus, the DC-DC converter 600 may not determine a short circuit defect of the display panel 100 in the low-power mode.

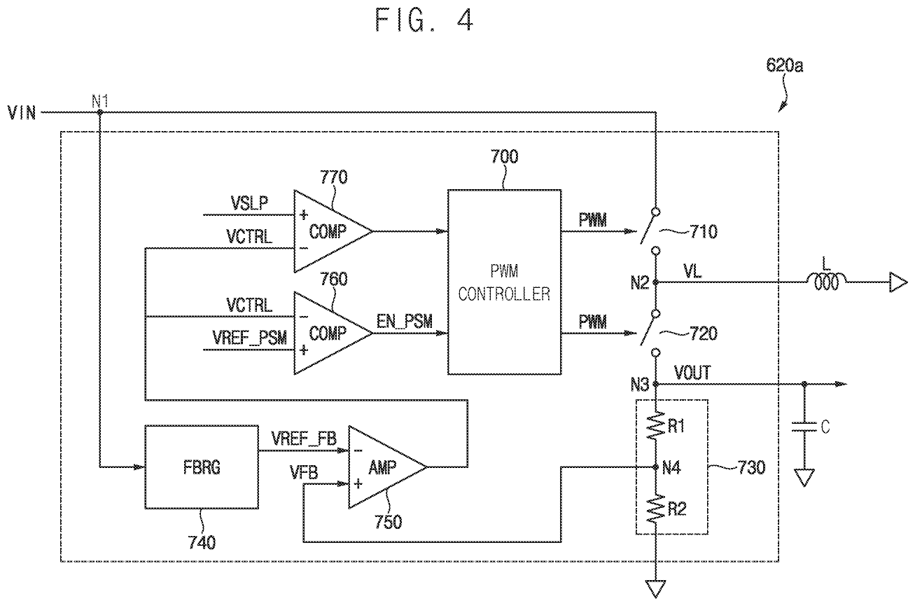

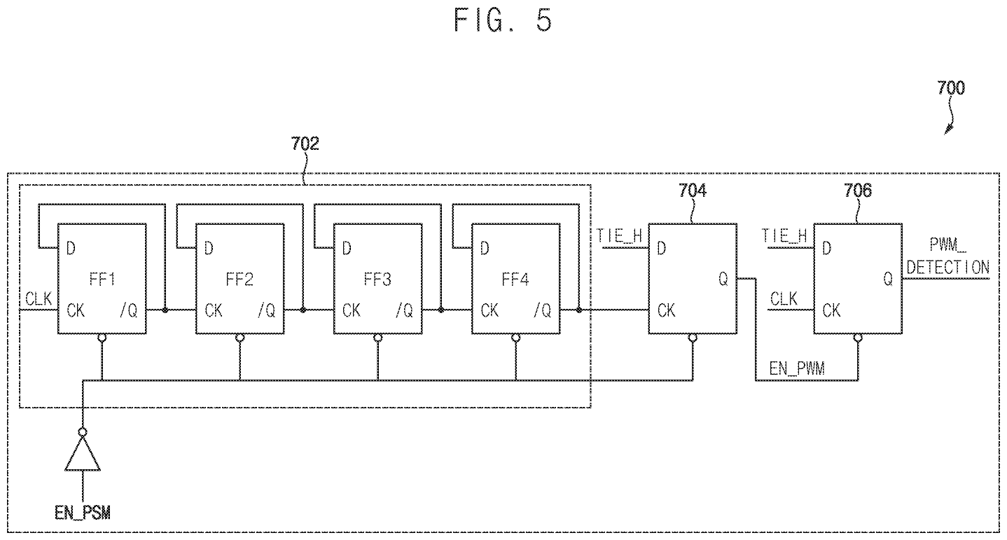

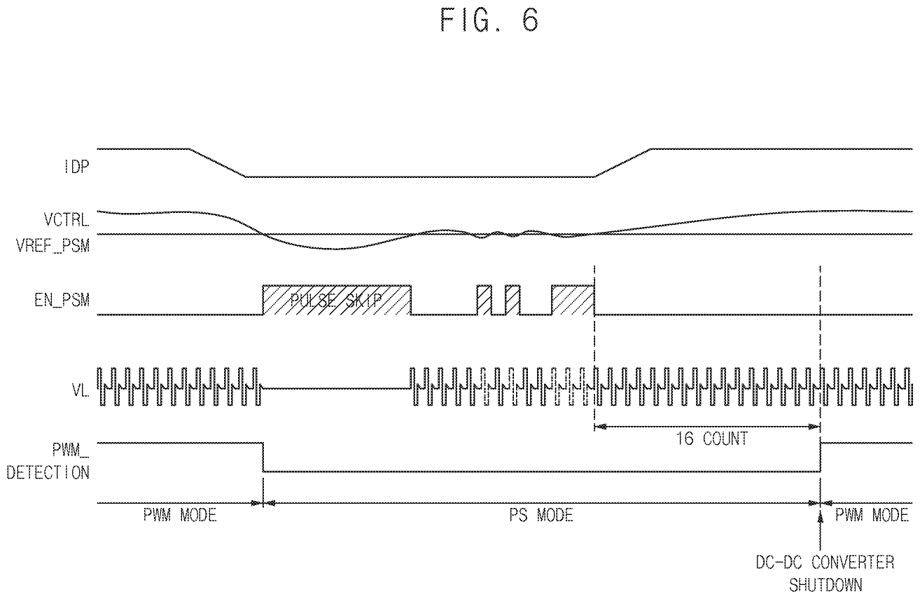

FIG. 4 is a block diagram for illustrating an embodiment of a second converter 620a of FIG. 2. FIG. 5 is a block diagram for illustrating a controller 700 of FIG. 3. FIG. 6 is a timing diagram for illustrating an operation of the controller 700 of FIG. 3 when the DC-DC converter 600 is shut down due to the short circuit defect of the display panel 100 in the low-power mode.

Referring to FIGS. 1 to 6, the second converter 620a may include a switcher to generate an output voltage VOUT based on the external input voltage VIN, and the controller 700 to control the switcher based on the pulse width modulation signal PWM. The output voltage VOUT may be the second power voltage ELVSS. The switcher may include a first switching element 710, a second switching element 720, a voltage divider 730, a feedback reference voltage generator 740, an error amplifier 750, a first comparator 760, and a second comparator 770.

The first switching element 710 may be connected between a first node N1 and a second node N2. The first node N1 may receive the external input voltage VIN. The first switching element 710 may include transistors. The first switching element 710 may receive the pulse width modulation signal PWM from the controller 700, may turn on based on the pulse width modulation signal PWM, and may control a current to flow through an inductor L. The inductor L may be connected between the second node N2 and a ground. An inductor voltage VL (i.e., a voltage of the second node N2) may be determined by a current flowing through the inductor L. The output voltage VOUT may be controlled by the inductor voltage VL.

The second switching element 720 may be connected between the second node N2 and the third node N3. The second switching element 720 may include transistors. The first switching element 710 may receive the pulse width modulation signal PWM from the controller 700, and may turn on alternately with the second switching element 720 based on the pulse width modulation signal PWM. (In other words, the first switching element 710 and the second switching element 720 may be alternately switched based on the pulse width modulation signal PWM.) Thus, after the first switching element 710 turns on and electromotive force is generated in the inductor L, the second switching element 720 may turn on so that the external input voltage VIN may be converted into the output voltage VOUT and the output voltage VOUT may be output to the third node N3. The second node N2 may be a common node of the first switching element 710, the second switching element 720, and the inductor L.

In an embodiment, some components of the first switching element 710 and some components of the second switching element 720 may operate in the low-power mode.

The voltage divider 730 may be connected between the third node N3 and the ground. The voltage divider 730 may include resistors R1 and R2 connected to the third node N3 to which the output voltage VOUT is applied. The voltage divider 730 may generate a feedback voltage VFB by dividing the output voltage VOUT. In an embodiment, a capacitor C may be connected between the third node N3 and the ground, but is not limited thereto.

The feedback reference voltage generator 740 may generate a feedback reference voltage VREF_FB based on the external input voltage VIN, and may output the feedback reference voltage VREF_FB to the error amplifier 750.

The error amplifier 750 may amplify a voltage difference between the feedback voltage VFB and the feedback reference voltage VREF_FB to output a control voltage VCTRL.

In an embodiment, in the low-power mode, the second converter 620a may operate in a pulse skip mode PS MODE or a pulse width modulation mode (PWM MODE). The first comparator 760 may operate in the pulse skip mode PS MODE, and the second comparator 770 may operate in the pulse width modulation mode PWM MODE. The pulse skip mode PS MODE may be a mode in which some of the active pulses of the pulse width modulation signal PWM are skipped. The pulse width modulation mode PWM MODE may be a mode in which the active pulses of the pulse width modulation signal PWM are not skipped.

The first comparator 760 may compare the control voltage VCTRL with a skip reference voltage VREF_PSM in the pulse skip mode PS MODE, and output a skip control signal EN_PSM. In an embodiment, when the control voltage VCTRL is lower than the skip reference voltage VREF_PSM, the skip control signal EN_PSM may be at a relatively high level, and when the control voltage VCTRL is higher than the skip reference voltage VREF_PSM, the skip control signal EN_PSM may be at a relatively low level, for example.

The controller 700 may output the pulse width modulation signal PWM. The controller 700 may control switching (i.e., turn-on/turn-off) of the first switching element 710 and the second switching element 720. The first switching element 710 and the second switching element 720 may alternately turn on.

The controller 700 may output the pulse width modulation signal PWM based on the skip control signal EN_PSM to reduce power consumption in the low-power mode. The driving current IDP of the display panel 100 may be relatively low in the low-power mode. When the driving current IDP of the display panel 100 is low, the luminance of images may be low. Thus, when the driving current IDP of the display panel 100 is low, a difference in the luminance of images may not be recognized even when the controller 700 skips some of the active pulses of the pulse width modulation signal PWM. In the low-power mode, when the skip control signal EN_PSM is at a relatively high level, the controller 700 may skip the active pulses of the pulse width modulation signal PWM. In the low-power mode, when the skip control signal EN_PSM is at a relatively low level, the controller 700 may not skip the active pulses of the pulse width modulation signal PWM.

The DC-DC converter 600 may operate in the pulse skip mode PS MODE to reduce power consumption when the driving current IDP of the display panel 100 is equal to or less than a predetermined voltage. In an embodiment, when the driving current IDP of the display panel 100 is about 20 milliamperes (mA) or less, the DC-DC converter 600 may operate in the pulse skip mode PS MODE, for example. When the driving current IDP of the display panel 100 is equal to or greater than a predetermined voltage, the DC-DC converter 600 may be switched from the pulse skip mode PS MODE to the pulse width modulation mode PWM MODE and may determine a short circuit defect of the display panel 100. In an embodiment, when the driving current IDP of the display panel 100 is about 30 mA or more, the DC-DC converter 600 may be switched from the pulse skip mode PS MODE to the pulse width modulation mode PWM MODE and may determine the short circuit defect of the display panel 100, for example.

As described above, however, a current sensor used to determine the short circuit defect of the display panel 100 may not operate in the low-power mode. However, when the driving current IDP of the display panel 100 increases, the number of switching of the inductor voltage VL may increase. The number of switching of the inductor voltage VL may be determined by the number of switching of the pulse width modulation signal PWM (i.e., the number of turn-on/turn-off operations). Thus, the DC-DC converter 600 may determine the short circuit defect of the display panel 100 based on the number of switching of the pulse width modulation signal PWM.

When the skip control signal EN_PSM is at a relatively high level, the controller 700 may skip the active pulses of the pulse width modulation signal PWM, and the controller 700 may not count the number of switching of the pulse width modulation signal PWM. When the skip control signal EN_PSM is at a relatively low level, the controller 700 may not skip the active pulses of the pulse width modulation signal PWM, and the controller 700 may count the number of switching of the pulse width modulation signal PWM to generate a count value. When the count value is equal to or greater than a reference count value, the driving current IDP of the display panel 100 may increase, and the low-power mode of the DC-DC converter 600 may be switched from the pulse skip mode PS MODE to the pulse width modulation mode PWM MODE. Thus, when the count value is equal to or greater than the reference count value, the controller 700 may determine the short circuit defect of the display panel 100.

The controller 700 may include a counter 702, a switching control signal generator 704, and a short circuit defect signal generator 706. The counter 702 may include first to fourth flip-flops FF1 to FF4. In an embodiment, when the number of flip-flops is four, the reference count value may be 16, for example. In an embodiment, when the number of flip-flops is three, the reference count value may be 8, for example. In an embodiment, when the number of flip-flops is five, the reference count value RCNT may be 32, for example. The first to fourth flip-flops FF1 to FF4 may be cleared by the skip control signal EN_PSM.

The first flip-flop FF1 may output a first inverted output signal by the pulse width modulation clock signal CLK as a clock signal, and may feedback the first inverted output signal as a first input signal at the same time. The second flip-flop FF2 may output a second inverted output signal by the first inverted output signal as the clock signal, and may feedback the second inverted output signal as the second input signal at the same time. The third flip-flop FF3 may output a third inverted output signal by the second inverted output signal as the clock signal, and may feedback the third inverted output signal as the third input signal at the same time. The fourth flip-flop FF4 may output a fourth inverted output signal by the third inverted output signal as the clock signal, and may feedback the fourth inverted output signal as the fourth input signal at the same time.

The switching control signal generator 704 may output a switching control signal EN_PWM by the fourth inverted output signal as the clock signal. The switching control signal generator 704 may be cleared by the skip control signal EN_PSM. In an embodiment, the switching control signal generator 704 may receive a signal TIE_H, but is not limited thereto.

The short circuit defect signal generator 706 may output a short circuit defect signal PWM_DETECTION by the pulse width modulation clock signal CLK as the clock signal. The switching control signal generator 704 may be cleared by the switching control signal EN_PWM. The low-power mode of the DC-DC converter 600 may be switched from the pulse skip mode PS MODE to the pulse width modulation mode PWM MODE based on the short circuit defect signal PWM_DETECTION. In an alternative embodiment, the display panel 100 may be determined to include the short circuit defect based on the short circuit defect signal PWM_DETECTION, and thus the DC-DC converter 600 may be shut down. In an embodiment, when the count value is equal to or greater than the reference count value in the pulse skip mode PS MODE of the low-power mode, the short circuit defect signal PWM_DETECTION may be converted from a relatively low level to a relatively high level, the low-power mode of the DC-DC converter 600 may be converted from the pulse skip mode PS MODE to the pulse width modulation mode PWM MODE, and the DC-DC converter 600 may be shut down because the display panel 100 is determined to include the short circuit defect, for example. In an embodiment, the short circuit defect signal generator 706 may receive a signal TIE_H, but is not limited thereto.

As such, the DC-DC converter 600 may include the switcher to generate the output voltage VOUT based on the external input voltage VIN, and the controller 700 to control the switcher. The controller 700 may generate the count value by counting the number of switching of the pulse width modulation signal PWM in the pulse skip mode PS MODE of the low-power mode. Accordingly, when the count value is equal to or greater than the reference count value, the short circuit defect may be determined.

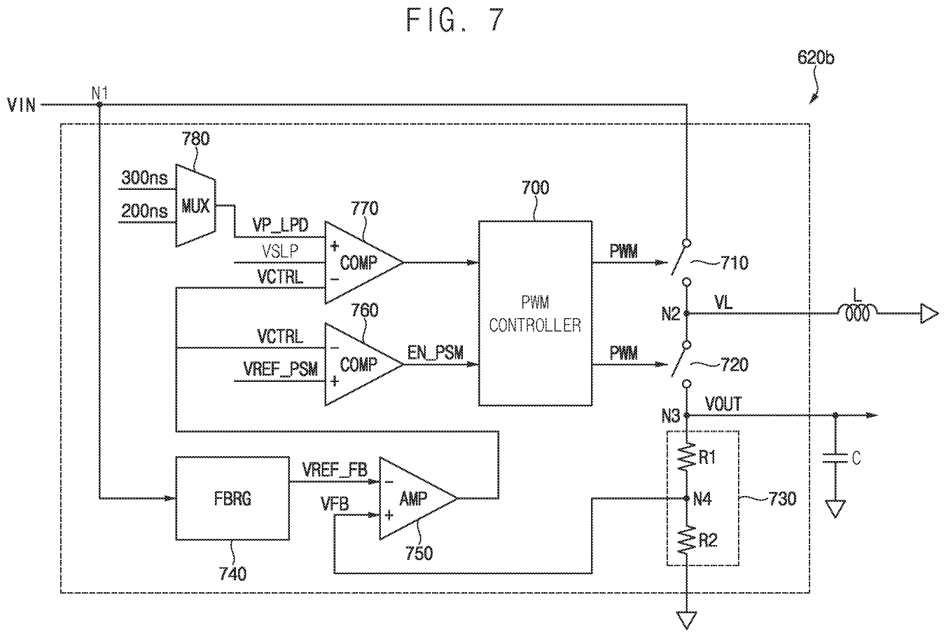

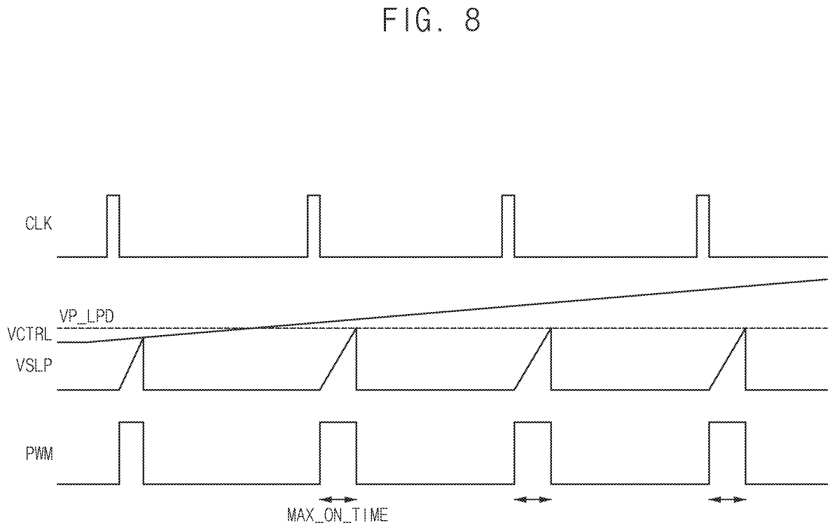

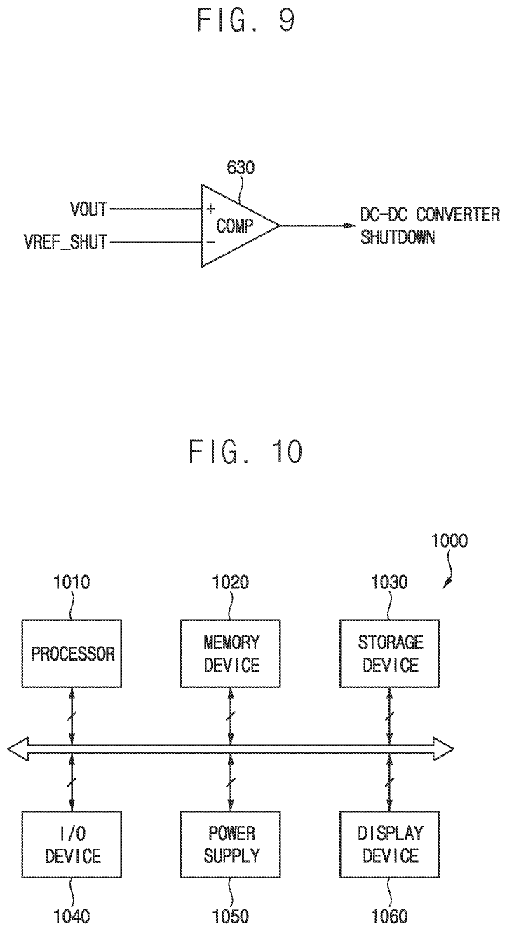

FIG. 7 is a block diagram for illustrating an embodiment of the second converter 620a of FIG. 2. FIG. 8 is a timing diagram for illustrating an operation of the second converter 620b of FIG. 7. FIG. 9 is a conceptual diagram for illustrating the short circuit defect comparator of FIG. 7.

The second converter 620b of FIG. 7 is substantially the same as the first converter 620a of FIG. 4 except for the second comparator and the controller. Thus, repetitive descriptions of the same or corresponding components will be omitted.

Referring to FIGS. 1 to 9, the second comparator 770 may operate in the pulse width modulation mode PWM MODE. The second comparator 770 may compare a slope voltage VSLP with the control voltage VCTRL and the pulse width modulation reference voltage VP_LPD in the pulse skip mode PS MODE to output the pulse width modulation signal PWM. In an embodiment, when the pulse width modulation clock signal CLK has a falling edge, the slope voltage VSLP may gradually increase, for example. In an embodiment, when the pulse width modulation clock signal CLK has a rising edge, the slope voltage VSLP may gradually increase, for example. When the slope voltage VSLP gradually increases, the pulse width modulation signal PWM may have an active level. The slope voltage VSLP may gradually increase so that the slope voltage VSLP may be equal to the control voltage VCTRL or the pulse width modulation reference voltage VP_LPD. When the slope voltage VSLP gradually increases so that the slope voltage VSLP becomes equal to the control voltage VCTRL or the pulse width modulation reference voltage VP_LPD, the slope voltage VSLP may have an inactive level. When the slope voltage VSLP has an inactive level, the pulse width modulation signal PWM may have an inactive level. The pulse width modulation reference voltage VP_LPD may be a voltage set to control the maximum on-time MAX_ON_TIME of the pulse width modulation signal PWM.

The switcher may further include a multiplexer 780 to select and output one of the pulse width modulation reference voltages VP_LPD. The multiplexer 780 may select one of the pulse width modulation reference voltages VP_LPD to control the maximum on-time MAX_ON_TIME of the pulse width modulation signal PWM, and output the same to the second comparator 770. A frequency of the pulse width modulation signal PWM may be determined based on the maximum on-time MAX_ON_TIME. In an embodiment, when the maximum on-time MAX_ON_TIME is about 200 nanoseconds (ns), the frequency of the pulse width modulation signal PWM may be about 500 kilohertz (kHz), for example. In an embodiment, when the maximum on-time MAX_ON_TIME is about 300 ns, the frequency of the pulse width modulation signal PWM may be about 250 kHz, for example.

In addition, when the display panel 100 includes the short circuit defect (e.g., the fine short circuit defect), the driving current IDP of the display panel 100 may increase, and the output voltage VOUT of the DC-DC converter 600 may decrease. When the output voltage VOUT decreases to be equal to or less than the short circuit defect reference voltage VREF_SHUT, the DC-DC converter 600 may determine the short circuit defect of the display panel 100.

As such, the DC-DC converter 600 may include the switcher to generate the output voltage VOUT based on the external input voltage VIN, and the controller 700 to control the switcher. The controller 700 may compare the slope voltage VSLP with the control voltage VCTRL and the pulse width modulation reference voltage VP_LPD in the pulse skip mode PS MODE of the low-power mode to control a width of the active pulse of the pulse width modulation signal PWM. The switcher may determine the short circuit defect when the output voltage VOUT is lower than the short circuit defect reference voltage VREF_SHUT based on a comparison result by the short circuit defect comparator 630.

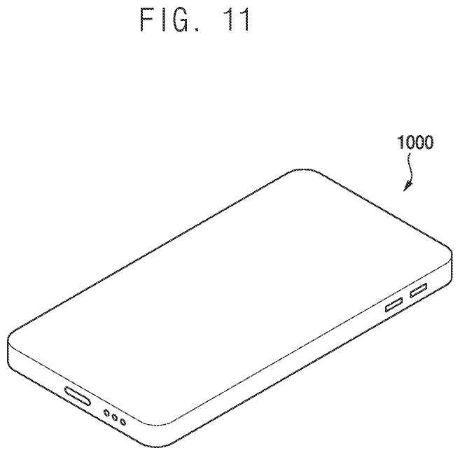

FIG. 10 is a block diagram for illustrating an electronic device 1000. FIG. 11 is a diagram for illustrating an embodiment in which the electronic device 1000 of FIG. 10 is implemented as a smart phone.

Referring to FIGS. 10 and 11, an electronic device 1000 may include a processor 1010, a memory device 1020, a storage device 1030, an input/output (“I/O”) device 1040, a power supply 1050, and a display device 1060. The display device 1060 may be a display device 10 in FIG. 1. In addition, the electronic device 1000 may further include a plurality of ports for communicating with a video card, a sound card, a memory card, a universal serial bus (“USB”) device, other electronic device, or the like.

In an embodiment, as illustrated in FIG. 11, the electronic device 1000 may be implemented as a smart phone. However, the electronic device 1000 is not limited thereto. In an embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”) device, or the like, for example.

The processor 1010 may perform various computing functions. The processor 1010 may be a micro processor, a central processing unit (“CPU”), an application processor (“AP”), or the like. The processor 1010 may be coupled to other components via an address bus, a control bus, a data bus, or the like. Further, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like and/or at least one volatile memory device such as a dynamic random access memory (“DRAM”) device, a static random access memory (“SRAM”) device, a mobile DRAM device, or the like.

The storage device 1030 may include a solid state drive (“SSD”) device, a hard disk drive (“HDD”) device, a compact disc read-only memory (“CD-ROM”) device, or the like.

The I/O device 1040 may include an input device such as a keyboard, a keypad, a mouse device, a touch-pad, a touch-screen, or the like, and an output device such as a printer, a speaker, or the like. In some embodiments, the I/O device 1040 may include the display device 1060.

The power supply 1050 may provide power for operations of the electronic device 1000.

The display device 1060 may be connected to other components through buses or other communication links.

The inventive concepts may be applied to any display device and any electronic device including the touch panel. In an embodiment, the inventive concepts may be applied to a mobile phone, a smart phone, a tablet computer, a digital television (“TV”), a three dimensional (“3D”) TV, a personal computer (“PC”), a home appliance, a laptop computer, a personal digital assistant (“PDA”), a portable multimedia player (“PMP”), a digital camera, a music player, a portable game console, a navigation device, etc., for example.

The foregoing is illustrative of the inventive concept and is not to be construed as limiting thereof. Although a few embodiments of the inventive concept have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims. In the claims, means-plus-function clauses are intended to cover the structures described herein as performing the recited function and not only structural equivalents but also equivalent structures. Therefore, it is to be understood that the foregoing is illustrative of the inventive concept and is not to be construed as limited to the illustrative embodiments disclosed, and that modifications to the disclosed embodiments, as well as other embodiments, are intended to be included within the scope of the appended claims. The inventive concept is defined by the following claims, with equivalents of the claims to be included therein.

What is claimed is:

1. A direct current to direct current converter comprising:
a switcher which generates an output voltage based on an external input voltage; and
a controller which controls the switcher based on a pulse width modulation signal,
wherein the controller counts a number of switching of the pulse width modulation signal in a pulse skip mode of a low-power mode, generates a count value, and determines a short circuit defect when the count value is equal to or greater than a reference count value.

2. The direct current to direct current converter of claim 1, wherein the controller converts the pulse skip mode of the low-power mode into a pulse width modulation mode when the count value is equal to or greater than the reference count value.

3. The direct current to direct current converter of claim 1, wherein the switcher comprises:
a voltage divider which divides the output voltage and generates a feedback voltage;
an error amplifier which amplifies a voltage difference between the feedback voltage and a feedback reference voltage and outputs a control voltage; and
a comparator which compares the control voltage with a skip reference voltage and outputs a skip control signal.

4. The direct current to direct current converter of claim 3, wherein the controller skips active pulses of the pulse width modulation signal when the skip control signal is at a relatively high level, and does not skip the active pulses of the pulse width modulation signal when the skip control signal is at a relatively low level.

5. The direct current to direct current converter of claim 3, wherein the controller resets the count value when the skip control signal is at a relatively high level, counts the number of switching of the pulse width modulation signal and generates the count value when the skip control signal is at a relatively low level.

6. The direct current to direct current converter of claim 1, wherein the controller comprises a first flip-flop to a fourth flip-flop, in which
the first flip-flop outputs a first inverted output signal, which is an inverted output signal of the first flip-flop, using a pulse width modulation clock signal, and simultaneously feeds back the first inverted output signal to a first input signal, which is an input signal of the first flip-flop,
the second flip-flop outputs a second inverted output signal, which is an inverted output signal of the second flip-flop, using the first inverted output signal, and simultaneously feeds back the second inverted output signal to a second input signal, which is an input signal of the second flip-flop,
the third flip-flop outputs a third inverted output signal, which is an inverted output signal of the third flip-flop, using the second inverted output signal, and simultaneously feeds back the third inverted output signal to a third input signal, which is an input signal of the third flip-flop, and
the fourth flip-flop outputs a fourth inverted output signal, which is an inverted output signal of the fourth flip-flop, using the third inverted output signal, and simultaneously feeds back the fourth inverted output signal to a fourth input signal, which is an input signal of the fourth flip-flop.

7. A direct current to direct current converter comprising:
a switcher which generates an output voltage based on an external input voltage; and
a controller which controls the switcher,
wherein the controller compares a slope voltage with a control voltage and a pulse width modulation reference voltage in a pulse width modulation mode of a low-power mode to control a width of an active pulse of a pulse width modulation signal, and
wherein the switcher determines a short circuit defect when the output voltage is lower than a short circuit defect reference voltage.

8. The direct current to direct current converter of claim 7, wherein the slope voltage gradually increases when a pulse width modulation clock signal has a falling edge.

9. The direct current to direct current converter of claim 8, wherein the pulse width modulation signal has an active level when the slope voltage gradually increases.

10. The direct current to direct current converter of claim 7, wherein the slope voltage has an inactive level when the slope voltage gradually increases to be equal to the control voltage or the pulse width modulation reference voltage.

11. The direct current to direct current converter of claim 10, wherein the pulse width modulation signal has an inactive level when the slope voltage has the inactive level.

12. The direct current to direct current converter of claim 7, wherein the switcher comprises:
a voltage divider which divides the output voltage and generates a feedback voltage;
an error amplifier which amplifies a voltage difference between the feedback voltage and a feedback reference voltage and outputs the control voltage; and
a comparator which compares the slope voltage with the control voltage and the pulse width modulation reference voltage and outputs a maximum on-time signal.

13. The direct current to direct current converter of claim 12, wherein the switcher further comprises a multiplexer which selects and outputs one of the pulse width modulation reference voltage among pulse width modulation reference voltages.

14. The direct current to direct current converter of claim 12, wherein the switcher further comprises a short circuit defect comparator which compares the output voltage with the short circuit defect reference voltage.

15. A display device comprising:
a display panel; and
a direct current to direct current converter which applies an output voltage to the display panel,
wherein the direct current to direct current converter includes a switcher which generates the output voltage based on an external input voltage, and a controller which controls the switcher based on a pulse width modulation signal, and
the controller counts a number of switching of the pulse width modulation signal in a pulse skip mode of a low-power mode, generates a count value, and determines a short circuit defect when the count value is equal to or greater than a reference count value.

16. The display device of claim 15, wherein the controller converts the pulse skip mode of the low-power mode into a pulse width modulation mode when the count value is equal to or greater than the reference count value.

17. The display device of claim 15, wherein the switcher comprises:
a voltage divider which divides the output voltage and generates a feedback voltage;
an error amplifier which amplifies a voltage difference between the feedback voltage and a feedback reference voltage and outputs a control voltage; and
a comparator which compares the control voltage with a skip reference voltage and outputs a skip control signal.

18. The display device of claim 17, wherein the controller skips active pulses of the pulse width modulation signal when the skip control signal is at a relatively high level, and does not skip the active pulses of the pulse width modulation signal when the skip control signal is at a relatively low level.

19. The display device of claim 17, wherein the controller resets the count value when the skip control signal is at a relatively high level, counts the number of switching of the pulse width modulation signal and generates the count value when the skip control signal is at a relatively low level.

20. The direct current to direct current converter of claim 15, wherein the controller comprises a first flip-flop to a fourth flip-flop, in which
the first flip-flop outputs a first inverted output signal, which is an inverted output signal of the first flip-flop, using a pulse width modulation clock signal, and simultaneously feeds back the first inverted output signal to a first input signal, which is an input signal of the first flip-flop,
the second flip-flop outputs a second inverted output signal, which is an inverted output signal of the second flip-flop, using the first inverted output signal, and simultaneously feeds back the second inverted output signal to a second input signal, which is an input signal of the second flip-flop,
the third flip-flop outputs a third inverted output signal, which is an inverted output signal of the third flip-flop, using the second inverted output signal, and simultaneously feeds back the third inverted output signal to a third input signal, which is an input signal of the third flip-flop, and
the fourth flip-flop outputs a fourth inverted output signal, which is an inverted output signal of the fourth flip-flop, using the third inverted output signal, and simultaneously feeds back the fourth inverted output signal to a fourth input signal, which is an input signal of the fourth flip-flop.
